(19) United States
(12) Patent Application Publication
(10) Pub. No.: US 2004/0150045 A1
(43) Pub. Date: Aug. 5, 2004

(54) LSI alleviating hysteresis of delay time

(75) Inventors: Makoto Nonaka, Kanagawa (JP); Shuji Takahashi, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/739,008

(22) Filed: Dec. 19, 2003

(30) Foreign Application Priority Data
Dec. 19, 2002 (JP) 2002-367477

(51) Int. Cl. H01L 27/01

(52) U.S. Cl. 257/347

(57) ABSTRACT

A buffer circuit of an LSI includes first inverter and a second inverter cascaded from the first inverter, each of the first and second inverters including a pMOSFET and an nMOSFET. The body areas or backgates of the pMOSFETs operating in opposite phases and body areas of the nMOSFETs operating in opposite phases are respectively coupled together via a coupling line, to thereby prevent hysteresis or fluctuation of the delay time in the operation of the buffer circuit.

### BACKGROUND OF THE INVENTION

(a) Field of the Invention

The present invention relates to a semiconductor integrated circuit (LSI) and, more particularly, to the structure of an LSI suited to a SOI LSI having a field-effect transistor (FET) in each of island semiconductor areas formed on an insulator film.

(b) Description of the Related Art

A silicon-on-insulator (SOI). structure generrally includes a silicon substrate, silicon oxide film formed thereon, and a silicon semiconductor layer formed on the silicon oxide film. The silicon layer includes a plurality of island semiconductor areas receiving therein respective semiconductor elements such as FETs.

Examples of a technique for improving operational speed of the FETs formed in the SOI LSI include one wherein the body areas of FETs are maintained at an electrically floating state. FIG. 12 exemplifies a SOI LSI having therein MOSFETs as typical FETs, wherein a semiconductor layer 13, such as made of silicon, is formed on an insulator film 12 formed on a silicon substrate 11, the semiconductor layer 13 being isolated by an isolation trench 14 into a plurality of isolated semiconductor areas. The plurality of isolated semiconductor areas include pMOS areas 13P and nMOS areas 13N electrically isolated from one another. Each of pMOSFET PT and nMOSFET NT formed in the pMOS area 13P and nMOS area 13N has gate insulation film 15, gate electrode G and source/drain regions 16P or 16N.

In FIG. 12, the pMOSFET PT is formed in the pMOS area 13P formed as an N-type diffused region and including therein P-type source/drain regions 16P, whereas the nMOSFET NT is formed in the nMOS area 13N formed as a P-type region and including therein N-type source/drain regions 16N.

The portion of the pMOS area 13P or nMOS area 13N formed outside the source/drain regions 16P or 16N and opposing the gate electrode is called “backgate area” or “body area” in this text. The body area is maintained at an electrically floating state, i.e., not fixed at a specific potential.

It is assumed that the MOSFETs such as illustrated in FIG. 12 are configured to form a two-stage buffer circuit, such as shown in FIG. 1, wherein two inverters are cascaded. The buffer circuit includes a first-stage inverter 31 including a first pMOSFET PT1 and a first nMOSFET NT1 connected in series between VDD source line and ground (GND) line. The gate electrodes of both the MOSFETs PT1 and PN1 are connected to an input terminal IN, and the node connecting together the MOSFETs PT1 and NT1 is connected to an intermediate node M. The buffer circuit includes a second-stage inverter 32 including a second pMOSFET PT2 and a second nMOSFET NT2 connected in series between VDD source line and GND line. The gate electrodes of both the MOSFETs PT2 and NT2 are connected to the intermediate node M, and the node connecting together the MOSFETs PT2 and NT2 is connected to an output terminal OUT.

The operation of the buffer circuit as described above is shown in the timing chart of FIG. 13. When the input signal IN rises from an initial low level to a high level at a first switch timing, the first pMOSFET PT1 is turned OFF and the first nMOSFET NT1 is turned ON whereby the potential of the intermediate node M falls from an initial high level to a low level. This allows the second pMOSFET PT2 and second nMOSFET NT2 to be turned ON and OFF, respectively, whereby the output signal OUT rises from an initial low level to a high level. Thereafter, at a second switch timing when the input signal IN falls from the high level to a low level, the first pMOSFET PT1 and the first nMOSFET NT1 are turned ON and OFF, respectively, whereby the potential of the intermediate mode M rises the low level to a high level. This allows the second pMOSFET PT2 and the second nMOSFET NT2 to be turned OFF and ON, respectively, whereby the output signal OUT falls from the high level to a low level.

Although the body areas of the MOSFETs PT1, PT2, NT1 and MT2 are maintained at the floating state in each stage of the buffer circuit as described above, the potential of each of the body areas is affected by the drain potential due to the leakage current between the body area and the drain/source of the MOSFET. Assuming that V(PB1), V(PB2), V(NB1) and V(NB2) are the potentials (body potentials) of the body areas of the MOSFETs PT1, PT2, NT1 and NT2, respectively, the profiles of theses body potentials V(PB1), is V(PB2), V(NB1) and V(NB2) are such that shown in the bottom of FIG. 13.

Specifically, for example, in the state of the initial low level of the input signal IN, body potential V(PB1) of the first pMOSFET PT1 assumes a VDD level, because the drain thereof is connected to the intermediate potential which assumes a VDD level and the source thereof is connected to the VDD source line. In this state, the threshold potential of the first pMOSFET PT1 assumes an ordinary value. In addition, body potential V(NB1) of the first nMOSFET NT1 assumes a level significantly higher than the GND level because the drain thereof is connected to the intermediate node at the high level and the source thereof is connected to the GND line. In this state, the threshold potential of the first nMOSFET NT1 assumes a lower value.

In the next stage, or first switch timing when the input signal IN rises from the initial low level to a high level, the intermediate node M falls to a low level and the output signal rises to a high level. In this state, body potential V(PB1) of the first pMOSFET PT1 falls from the VDD level due to the coupling by the leakage current between the drain and the body area of the first pMOSFET PT1, whereas body potential V(NB1) of the first nMOSFET NT1 falls from the significantly higher potential to a lower level almost equal to the GND level.

In the second switch timing when the input signal IN falls to a low level, the intermediate node M rises to a high level, whereas the output signal OUT falls to a low level. In this state, body potentials V(PB1) and V(NB1) of the MOSFETs PT1 and NT1 assume potentials similar to the initial potentials, as shown in FIG. 13, due to the coupling by the leakage current between the drain and body area of each of the MOSFETs PT1 and NT1.

It is to be noted that body potentials V(PB2) and V(NB2) of the MOSFETs PT2 and NT2 are determined by the influence of the output potential OUT which is either high or low.

In FIG. 13, body potential V(NB1) determines or affects the threshold potential of the first-stage inverter and body potential V(PB2) determines the threshold potential of the second-stage inverter in the first switch timing, as illustrated by the dots shown on body potentials V(NB1) and V(PB2), whereas body potential V(PB1) determines the threshold potential of the first-stage inverter and body potential V(NB2) determines the threshold potential of the second-stage inverter in the second switch timing, as illustrated by the dots shown on body potentials V(PB1) and V(NB2) in FIG. 13.

As described above, the floating levels of the body areas of the MOSFETs affect the threshold potential, wherein the body potentials of the pMOSFETs lower than the VDD level reduce the threshold potentials thereof, and the body potentials of the nMOSFETs higher than the GND level reduce the threshold potentials thereof. The reduction of the threshold potentials allows a higher operational speed of the MOSFETs, as described in Patent Publication JP-A-2001-16090. It is to be noted, however, that the publication recites that the body potential is determined by the capacitive coupling between the gate electrode and the body area, which is different from the coupling by the leakage current between the body area and the drain, as described in this text.

In the description to follow, it is examined for the case wherein the input signal IN is first switched from the initial high level to a low level, and then switched from the low level to a high level, as shown in FIG. 14, which case is different from the case shown in FIG. 13. In FIG. 14, the timing chart is shown similarly to FIG. 13 except that the body potentials are represented by V′(PB1), V′(PB2), V′(NB1) and V′(NB2).

Comparing the case of FIG. 14 against the case of FIG. 13, body potentials V(NB1) and V(PB2) determine the delay time during the first switch timing of switching from the low level to the high level in FIG. 13, as shown by dots therein, and body potentials V′(NB1) and V′(PB2) determine the delay time during the second switch timing of switching from the low level to the high level in FIG. 14, as shown by dots therein. Similarly, body potentials V(PB1) and V(NB2) determine the delay time during the second switch timing of switching from the high level to the low level in FIG. 13, as shown by dots therein, and body potentials V′(PB1) and V′(NB2) determine the delay time during the first switch timing of switching from the high level to the low level in FIG. 14, as shown by dots therein.

It will be understood from FIGS. 13 and 14 that relationships V(NB1)≠V′(NB1), V(NB2)≠V′(NB2), V(PB1)≠V′(PB1) and V(PB2)≠V′(PB2) hold. Thus, the delay time during the switching is different between the cases of FIGS. 13 and 14, wherein delay time of the first switch timing from the initial low level to a high level is different from the delay time of the second switch timing from the temporary low level to a high level, and the delay time of the first switch timing from the initial high level to a low level is different from the delay time of the second switch timing from the temporary high level to a low level.

As described above, the body potentials of MOSFETs are different between the case of the initial, steady low level and the case of the initial, steady high level in the buffer circuit, whereby the delay time of the switching is different between both the cases. That is, the delay time of the signal inversion in the buffer circuit has a hysteresis therein.

It may be considered that the body areas of the MOSFETs be fixed at the VDD or GND potential for solving the above hysteresis; however, this suppresses the high-speed operation of the MOSFETs obtained by the floating body areas.

### SUMMARY OF THE INVENTION

In view of the above problems in the conventional techniques, it is an object of the present invention to provide a LSI including MOSFETs having floating body areas for obtaining a higher operational speed, and yet capable of suppressing hysteresis or fluctuations of the delay time in the operation of the MOSFETs.

The present invention provides a semiconductor integrated circuit (LSI) including an insulator layer, a plurality of island semiconductor areas formed on the insulator layer, and a plurality of first field-effect transistors (FETs) having a first conductivity-type and each formed in one of the semiconductor areas, each of the first FETs having a gate electrode, source/drain regions and a body area received in one of the semiconductor areas to oppose the gate electrode, wherein two of the first FETs operating in opposite phases have the respective body areas electrically coupled together via a coupling line and maintained at a floating state.

In accordance with the present invention, the floating state of the body areas allows a higher speed operation of the first FETs, whereas the electric coupling between the body areas of the FETs allows canceling of dynamic components of the potentials of the body areas to achieve a substantially constant body potential and thus suppression of hysteresis of the delay time in the operation of the FETs.

The above and other objects, features and advantages of the present invention will be more apparent from the following description, referring to the accompanying drawings.

### BRIEF DESCRIPTION OF THE DRAWINGS

FIG. 1 is a circuit diagram of a buffer circuit in a semiconductor integrated circuit according to an embodiment of the present invention.

FIG. 2 is a top plan view of the buffer circuit of FIG. 2.

FIG. 3 is a sectional view taken along line III-III in FIG. 2.

FIG. 4 is a timing chart of the buffer circuit of FIG. 1.

FIG. 5 is another timing chart of the buffer circuit of FIG. 1.

FIGS. 6A to 6C are sectional views of the buffer circuit of FIG. 1 during consecutive steps of fabrication thereof.

FIG. 7 is a top plan view of a buffer circuit in a semiconductor device according to a second embodiment of the present invention.

FIG. 8 is a sectional view of the buffer circuit of FIG. 7 taken along line VIII-VIII in FIG. 7.

FIGS. 9A and 9B are logic diagram of an AND circuit according to a first modification from the first embodiment.

FIGS. 10A and 10B are logic diagram of an OR circuit according to a second modification from the first embodiment.

FIGS. 11A and 11B are logic diagram of a logic circuit according to a third modification from the first embodiment.

FIG. 12 is a sectional view of a conventional LSI having a SOI structure.

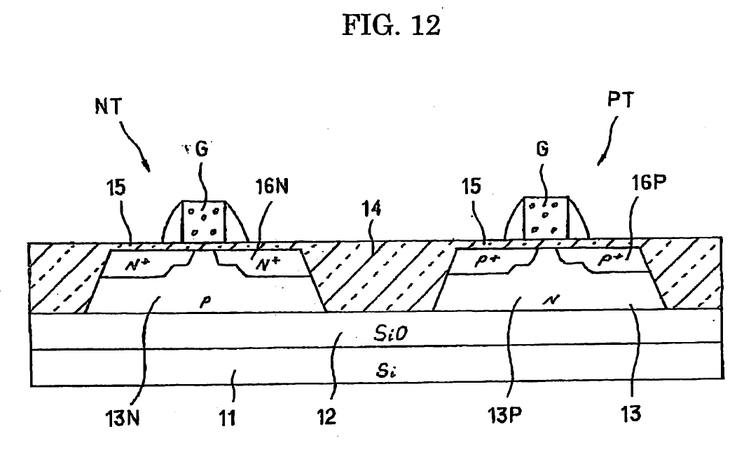

FIG. 13 is a timing chart of a buffer circuit in the conventional LSI of FIG. 12.

FIG. 14 is another timing chart of the buffer circuit in the conventional LSI of FIG. 12.

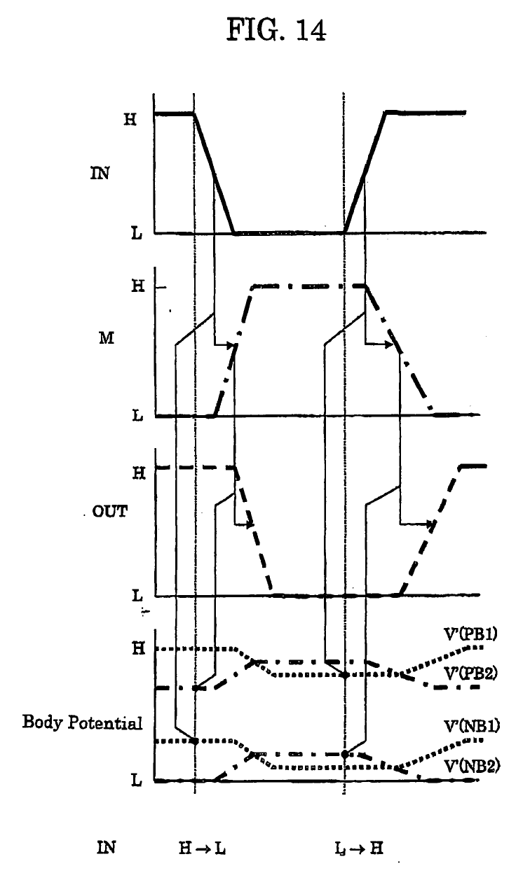

### PREFERRED EMBODIMENT OF THE INVENTION

Now, the present invention is more specifically described with reference to accompanying drawings, wherein similar constituent elements are designated by similar reference numerals throughout the drawings.

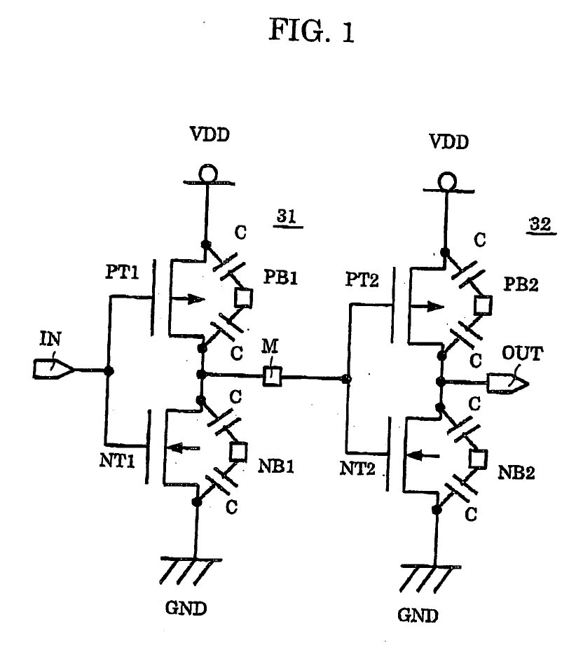

Referring to FIG. 1, an LSI, according to a first embodiment of the present invention includes a buffer circuit including a first-stage inverter 31 and a second-stage inverter 32 cascaded from the first-stage inverter 31. The first-stage inverter 31 includes a first pMOSFET PT1 and a first nMOSFET NT1 connected in series between the VDD source line and the GND line. The gates of both the MOSFETs PT1 and NT1 are connected to an input terminal IN, and the node connecting together the MOSFETs PT1 and NT1 is connected to an intermediate node M. The second-stage inverter 32 includes a second pMOSFET PT2 and a second nMOSFET NT2 connected in series between the VDD source line and the GND line. The gates of both the MOSFETs PT2 and NT2 are connected to the intermediate node M, and the node connecting together the MOSFETs PT2 and NT2 are connected to the output terminal OUT.

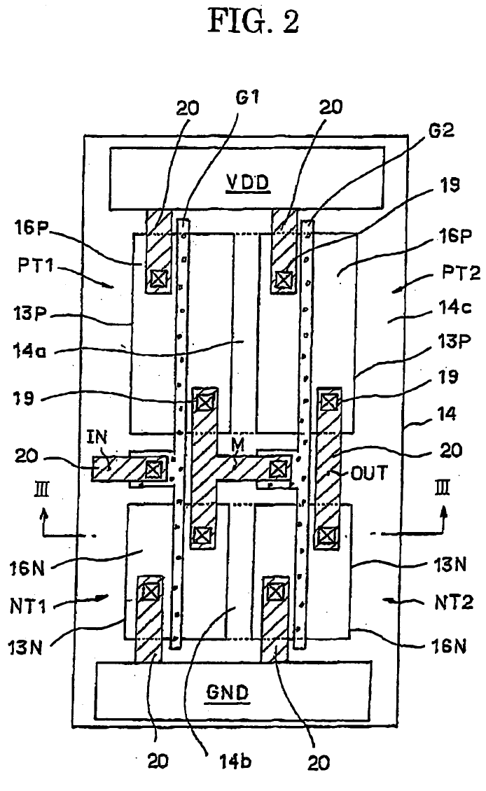

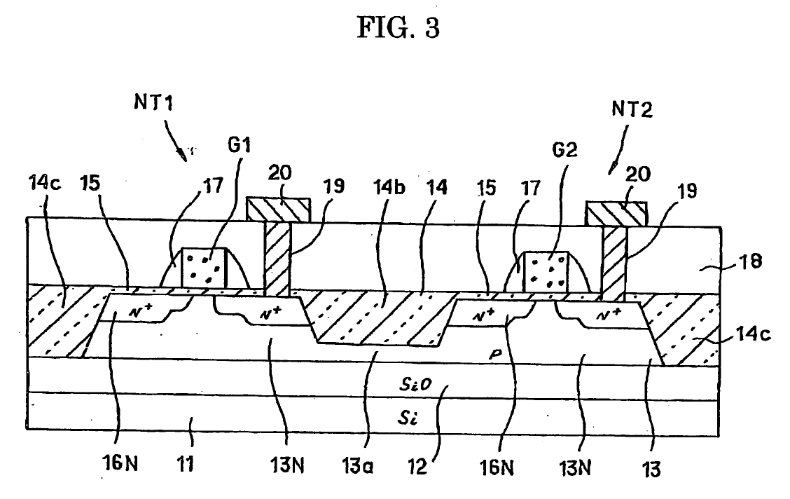

FIGS. 2 and 3 show a top plan view and a sectional view, respectively, of the buffer circuit of FIG. 1, wherein FIG. 3 is taken along line III-III in FIG. 2. A silicon oxide film 12 having a thickness of around several tens to several hundreds of nanometers (nm) is formed on the surface of a silicon substrate 11 by using a thermal oxidation technique. The silicon oxide film 12 is called herein a BOX film, on which a silicon semiconductor layer 13 having a thickness of around several tens to several hundreds of nanometers is formed. The semiconductor layer 13 includes a plurality of island pMOS areas 13P wherein N-type impurities are selectively introduced and a plurality of island nMOS areas 13N wherein P-type impurities are selectively introduced. The pMOS areas 13P and nMOS areas 13N are isolated from one another by a shallow trench isolation (STI) structure, i.e., by an isolation insulator film 14. Each of the first and second pMOSFETs PT1 and PT2 is formed in each pMOS area 13P, whereas each of the first and second nMOSFETs NT1 and NT2 is formed in each nMOS area 13N.

The portion of each pMOS area 13P or nMOS area 13N outside the source/drain regions 16P and 16N is referred to as a body area, which is denoted by PB1, PB2, NB1 or NB2 in FIG. 1. A gate oxide film 15 is formed on the body area, wherein a first gate electrode G1 extends on the gate oxide film 15 over the body areas of pMOSFET PT1 and nMOSFET NT1 and a second gate electrode G2 extends on the gate oxide film 15 over the body areas of pMOSFET PT2 and nMOSFET NT2. In the surface regions of the pMOS areas 13P and nMOS areas 13N, there are provided P-type source/drain regions 16P and N-type source/drain regions 16N having a LDD structure on the body areas.

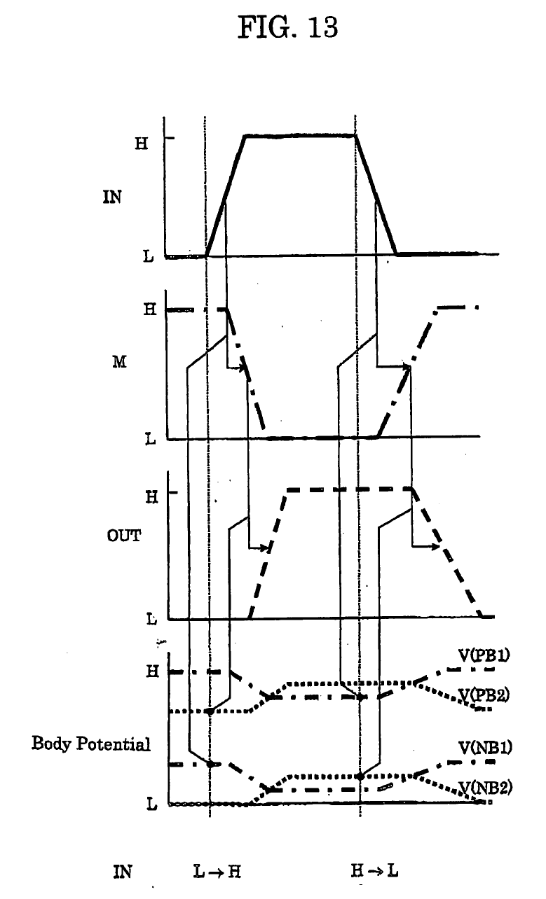

The portion 14a of the shallow trench isolating pMOSFET PT1 from pMOSFET PT2 and the portion 14b of the shallow trench isolating nMOSFET NT1 from nMOSFET NT2 do not reach the BOX film 12, as understood from FIG. 13 showing the portion 14b of the shallow trench. Thus, the body areas PB1 and PB2 of pMOSFETs PT1 and PT2 are electrically coupled together, and the body areas NB1 and NB2 of nMOSFETs NT1 and NT2 are electrically coupled together. The coupling is effected by the portions of the semiconductor layer 13 underlying the shallow trench 14, such as portion 13a shown in FIG. 3.

An interlayer dielectric film 18 is formed on the entire area including the gate electrodes G1 and G2 each having a side-wall oxide film 17. The interlayer dielectric film 18 has therein through-holes, in which high-melting-point-metal plugs 19, such as tungsten plugs, are formed. The tungsten plugs 19 connect overlying aluminum interconnects 20 to the gate electrodes G1 and G2 and drains of the MOSFETs, thereby configuring the circuit structure of FIG. 1.

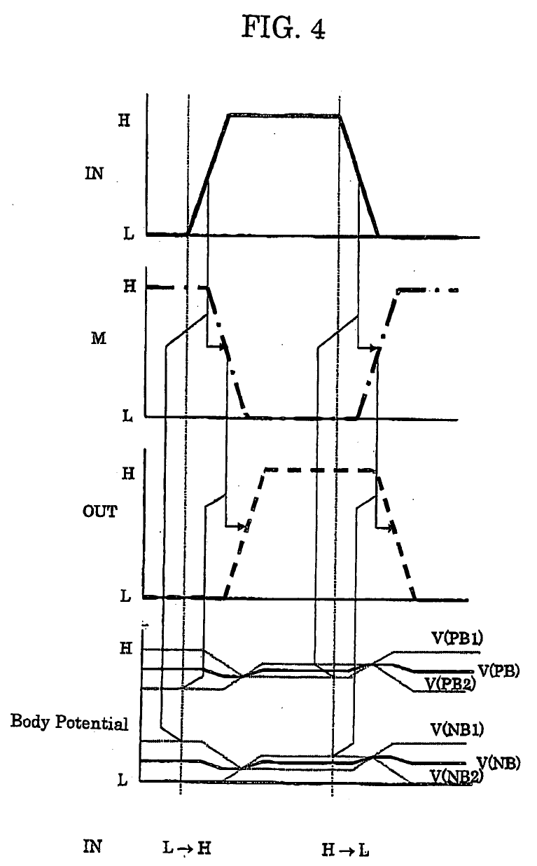

In operation of the buffer circuit of FIG. 1, as shown in FIG. 4, when the input signal IN stays at a low level, the first pMOSFET PT1 and first nMOSFET NT1 are ON and OFF, respectively, whereby the intermediate node M stays at a high level. Thus, the second pMOSFET PT2 and second nMOSFET NT2 are OFF and ON, respectively, whereby the output signal OUT stays at a high level.

When the input signal IN rises from the initial low level to a high level during the first switch timing, the first pMOSFET PT1 and first nMOSFET NT1 are turned OFF and ON, respectively, whereby the intermediate node M falls to a low level. Thus, the second pMOSFET PT2 and second nMOSFET NT2 are turned ON and OFF, respectively, whereby the output signal OUT falls to a low level. In this operation, the first pMOSFET PT1 and second pMOSFET PT2 operate substantially in opposite phases, wherein one of the pMOSFETs PT1 and PT2 is turned ON when the other is turned OFF and vice versa. Similarly, the first nMOSFET NT1 and the second nMOSFET NT2 operate substantially in opposite phases.

In the example of FIG. 4, the input signal IN rises from the initial low level to a high level and then falls to a low level. It is to be noted that each of the body areas of the MOSFETs is maintained at a floating level and the intermediate node M assumes a high level before the first switch timing. In this initial state, body potential V(PB1) of the first pMOSFET PT1 tends to assume a VDD level because the drain thereof is connected to the intermediate node M at the VDD level and the source thereof is connected to the VDD source line. On the other hand, body potential V(PB2) of the second pMOSFET PT2 tends to converge to a first level significantly lower than the VDD level because the drain thereof is connected to the output node OUT assuming a low level and the source thereof is connected to the VDD source line. The first level is determined by the ratio of the leakage current between the body area and the drain with respect to the leakage current between the body area and the source.

Since the body areas PB1 and PB2 of both the first and second pMOSFETs PT1 and PT2 are connected together, the potential of both the body areas PB1 and PB2 of the first and second pMOSFETs PT1 and PT2 stays at the mean potential of the above VDD level and the first level due to the canceling between the potential changes. Similarly, since the body areas NB1 and NB2 of both the first and second nMOSFETs NT1 and NT2 are connected together, the potential of both the body areas NB1 and NB2 of the nMOSFETs NT1 and NT2 stays at the mean value of the above potentials.

After the inversion of the input signal IN is completed during the first switch timing, the intermediate node M follows the inversion of the input signal IN to assume a low level slightly after the inversion, whereby the body potentials V(PB1) and V(NB1) of the first pMOSFET PT1 and first nMOSFET NT1 tend to fall toward the GND level. However, since the output signal OUT rises to a high level slightly after the potential inversion of the intermediate node M, body potentials V(PB2) and V(NB2) of the second pMOSFET PT2 and second nMOSFET NT2 are raised toward the VDD level. Thus, the fall of body potential V(PB1) and the rise of body potential V(PB2) cancel each other to thereby resume the mean potential V(PB), whereas the fall of body potential V(NB1) and the rise of body potential V(NB2) cancel each other to thereby resume the mean potential V(NB).

As described above, the dynamic fluctuations of the body potentials V(PB1) and V(NB1) are cancelled by the following changes of the body potentials V(PB2) and V(NB2), respectively, whereby the body potentials of the MOSFETs PT1, PT2, NT1 and NT2 are maintained at a substantially fixed mean potentials V(PB) and V(NB), as shown at the bottom of FIG. 4. This allows the first inverter 31 to have a lower threshold potential, wherein the body potential V(PB1) is lowered from the VDD level and the body potential V(NB1) is raised from the GND level. Thus, the floating level of body areas of the MOSFETs provides a reduction of the delay time during the first switch timing.

When the input signal IN again falls to a low level during the second switch timing, the MOSFETs PT1, PT2, NB1 and NB2 are again turned ON and OFF whereby the intermediate node M and the output node OUT assume a high level and a low level, respectively. In the second switch timing, the body potentials of MOSFETs are also maintained at the mean potentials V(PB) and V(NB) similarly to the first switch timing, thereby providing a reduction of the delay time during the second switch timing due to the floating level of the body potentials.

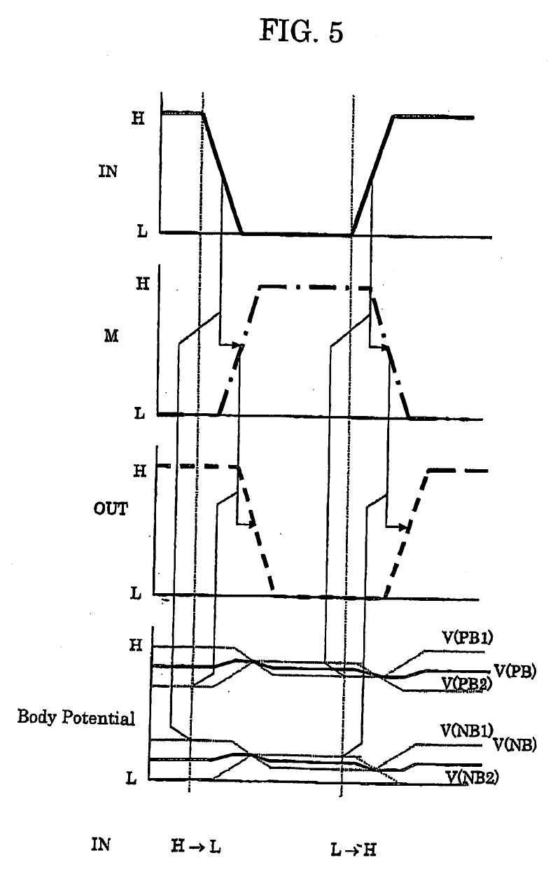

Referring to FIG. 5, there is shown another timing chart of operation of the buffer circuit of FIG. 1, wherein the input signal IN falls from the initial high level to a temporary low level, and then rises to a high level. In the initial state, due to a leakage current across the junction, body potential V(PB1) of the first pMOSFET PT1 tends to assume the first level significantly lower than the VDD level because the drain thereof is connected to the intermediate node M maintained at a low level and the source thereof is connected to the VDD source line. On the other hand, due to a leakage current across the junction, body potential V(PB2) of the second pMOSFET PT2 tends to assume a VDD level because the drain thereof is connected to the output node OUT assuming a high level and the source thereof is connected to the VDD source line.

The electrical coupling between the body areas PB1 and PB2 of both the pMOSFETs PT1 and PT2 allows both the body areas to stay at the mean potential V(PB) of the VDD level and the first level. Similarly, the electrical coupling between the body areas NB1 and NB2 of both the first and second nMOSFETs NT1 and NT2 allows both the body areas NB1 and NB2 of the nMOSFETs NT1 and NT2 to stay at the mean value V(NB) of the body potentials V(NB1) and V(NB2).

After the inversion of the input signal IN from the initial high level to the low level is completed during the first switch timing, the intermediate node M follows the signal inversion to assume a high level slightly after the signal inversion, whereby the body potentials V(PB1) and V(NB1) of the first pMOSFET PT1 and first nMOSFET NT1 tend to rise toward the VDD level. However, since the output signal OUT falls slightly after the potential inversion of the intermediate node M, body potentials V(PB2) and V(NB2) of the second pMOSFET PT2 and second nMOSFET NT2 fall toward the GND level. Thus, the rise of body potential V(PB1) and the subsequent fall of body potential V(PB2) cancel each other to thereby allow body potential V(PB1) to resume the mean potential V(PB), whereas the rise of body potential V(NB1) and the subsequent fall of body potential V(NB2) cancel each other to thereby allow body potential V(NB1) to resume the mean potential V(NB).

As described above, the dynamic fluctuations of the body potentials V(PB1) and V(NB1) are cancelled by the subsequent changes of the body potentials V(PB2) and V(NB2), respectively, whereby the body potentials of the MOSFETs PT1, PT2, NT1 and NT2 are maintained at a substantially fixed mean potentials V(PB) and V(NB). This allows the first inverter 31 to have a lower threshold potential, wherein the body potential V(PB1) is lowered from the VDD level and the body potential V(NB1) is raised from the GND level. Thus, the floating level of body areas of the MOSFETs provides a reduction of the delay time during the first switch timing.

When the input signal IN again rises to a high level during the second switch timing, the MOSFETs PT1, PT2, NB1 and NB2 are again turned ON and OFF whereby the intermediate node M and the output node OUT assume a low level and a high level, respectively. In the second switch timing, the body potentials of MOSFETs are also maintained at the mean potentials V(PB) and V(NB) similarly to the first switch timing, whereby the delay time is also reduced during the second switch timing due to the floating level of the body potentials.

As described above, during signal inversion of the output from the first inverter 31 due to the signal inversion of the input signal IN, the fluctuations of body potentials V(PB1) and V(NB1) of the first inverter 31 are cancelled by the change of the body potentials V(PB2) and V(NB2) of the second inverter 32, whereby body potentials are maintained at the mean potentials V(PB) and V(NB) to prevent the hysteresis of the delay time. This also applies to the inversion of the second inverter 32 to prevent the hysteresis of the delay time.

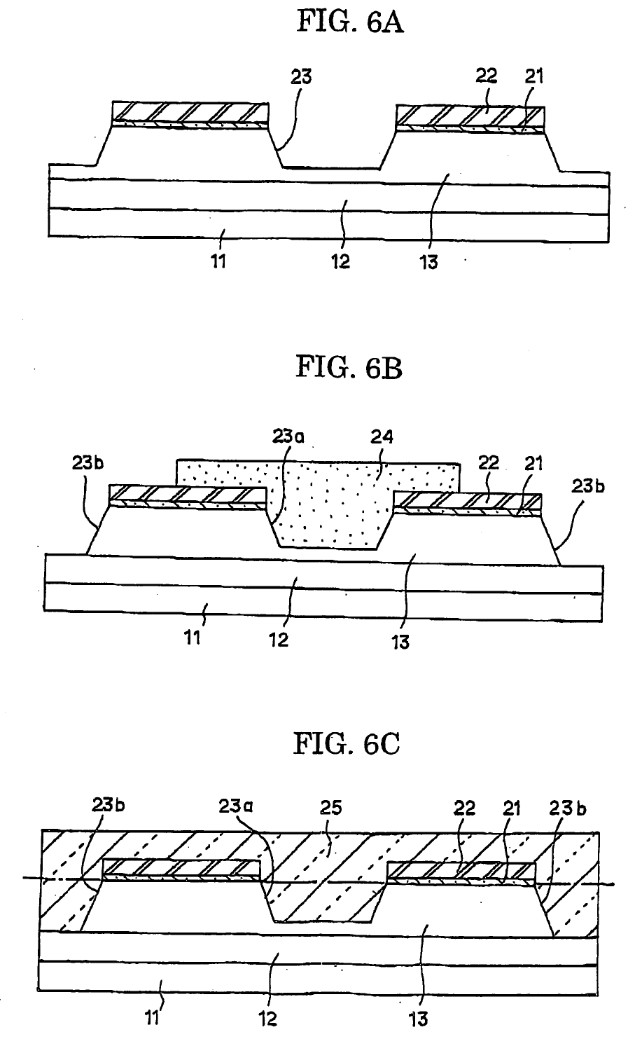

A method for manufacturing the buffer circuit of the present embodiment will be described with reference to FIGS. 6A to 6C which are also taken along line III-III in FIG. 2. As shown in FIG. 6A, a BOX film (silicon oxide film) 12 having a thickness of several tens to several hundreds of nanometers is formed on a silicon substrate 11 by using a thermal oxidation technique. Subsequently, a semiconductor layer 13 made of silicon is formed on the BOX film 12 as by using a bonding technique. The bonding technique is such that another silicon substrate is bonded onto the BOX film 12 and then polished to a specified thickness thereof to obtain the semiconductor layer 13.

Thereafter, pMOS areas 13P and nMOS areas 13N are formed by diffusion of P-type and N-type impurities into specified areas of the semiconductor layer 13, followed by thermal oxidation of the surface of the semiconductor layer 13 to obtain a pad oxide film 21. A silicon nitride film 22 is then deposited on the pad oxide film 21, followed by consecutive selective etching of the silicon oxide film 22 and the silicon oxide film 21 by using a photolithographic and etching technique. The semiconductor layer 13 is then etched by using the etched silicon nitride film 22 and the silicon oxide film 21 as an etching mask to form a lattice-shaped shallow trench 23 on the semiconductor layer 13, to obtain the structure of FIG. 6A. The shallow trench 23 isolates the MOS areas 13 from one another. The depth of the shallow trench 23 is smaller than the thickness of the semiconductor layer 13, whereby the bottom of the shallow trench 23 does not contact the surface of the BOX film 12.

Subsequently, as shown in FIG. 6B, a photoresist mask 24 is formed to selectively cover the portion 23a of the shallow trench 23 which isolates pMOSFET PT1 from pMOSFET PT2 and isolates nMOSFET NT1 from nMOSFET NT2. By using the photoresist mask 24 as an etching mask, the bottom of the other portion 23b of the shallow trench 23 other than the masked portion 23a is etched to the depth of the surface of the BOX film 12.

Subsequently, as shown in FIG. 6C, the photoresist mask 24 is removed and a silicon oxide film 25 is grown on the entire surface to a thickness larger than the depth of the etched portion 23b of the trench 23, thereby covering the entire surface of the semiconductor layer 13 and the trench 23. The silicon oxide film 25 is then polished by a chemical-mechanical polishing technique to leave the silicon oxide film 25 within the trench 23, followed by removing the silicon nitride film 22 and the silicon oxide film 21 to obtain the shallow trench structure 14 shown in FIG. 3.

The shallow trench 14 includes a first portion 14c in contact with the surface of the BOX film 12 at the locations isolating the pMOSFETs PT1 and PT2 from the nMOSFETs NT1 and NT2, and a second portion 14b apart from the surface of the BOX film 12 at the locations isolating pMOSFET PT1 from pMOSFET PT2 and isolating nMOSFET NT1 from nMOSFET NT2. Thus, the body areas PB1 and PB2 of pMOSFETs PT1 and PT2 are electrically connected together via the portion of the semiconductor layer 13, whereas the body areas NB1 and NB2 of nMOSFETs NT1 and NT2 are electrically connected together via the portion 13a of the semiconductor layer 13.

Subsequently, as shown in FIGS. 2 and 3, a gate oxide film 15 is formed on the main surface of the body areas PB1, PB2, NB1 and NB2 isolated from one another by the shallow trench 14. A polysilicon film is then deposited on the gate oxide film 15 and patterned to form gate electrodes G1 and G2, which extend on the gate oxide film 15 over the pMOSFETs PT1 and PT2 and nMOSFETs NT1 and NT2, respectively. Thereafter, P-type source/drain regions 16P are formed by selective ion-implanting of P-type impurities into the pMOS areas 13P by using a photoresist mask which covers the nMOS area 13N. Further, N-type source/drain regions 16N are formed by selective ion-implanting of N-type impurities into the nMOS area 13N by using another photoresist mask which covers the pMOS area 13P. It is to be noted that a side-wall structure of the gate electrode is used for obtain an LDD structure of the source/drain regions 16P and 16N before the ion-implanting.

After the MOSFETs PT1, PT2, NT1 and NT2 are thus formed, the interlayer dielectric film 18 is formed on the entire surface, and patterned to have through-holes therein. Contact plugs 19 made of a high-melting-point metal such as tungsten are received in the through-holes during deposition of an interconnect layer, which is patterned to form interconnects 20. Thus, the two-stage buffer circuit of FIG. 1 can be obtained

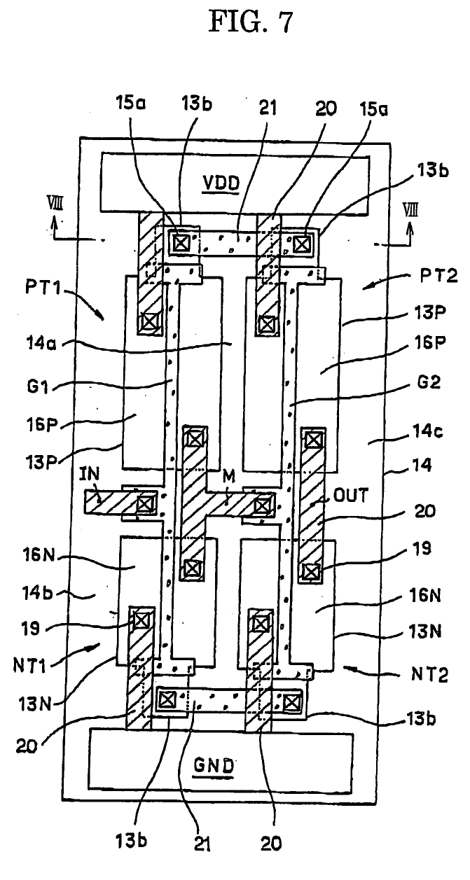

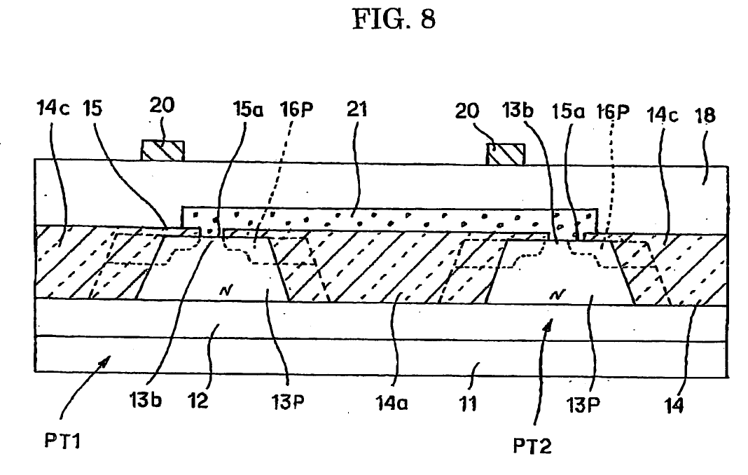

Referring to FIG. 7, there is shown a layout pattern of a buffer circuit according to a second embodiment of the present invention. FIG. 8 shows a sectional view thereof taken along line VIII-VIII in FIG. 7. MOSFETs PT1, PT2, NT1 and NT2 are isolated from one another by a shallow trench 14. The portions 14a and 14b of the shallow trench 14 isolating pMOSFETs PT1 from pMOSFET PT2 and nMOSFET NT1 from nMOSFET NT2, respectively, are in contact with the surface of the BOX film 12, differently from the configuration of the first embodiment. In the present embodiment, the body areas of pMOSFETs PT1 and PT2 are coupled together via a coupling line 21 and the body areas of nMOSFETs NT1 and NT2 are connected together via another, coupling line 21, both the coupling lines 21 overlying the semiconductor layer 13, as shown in FIG. 8.

More specifically, the layout pattern of the shallow trench 14 defines extensions 13b of the pMOS area 13P and nMOS area 13N, which protrude from the ends of the gate electrodes G1 and G2. The extensions of the pMOS areas 13P and extensions of the nMOS areas 13N are respectively coupled together via the coupling lines 21 which are formed on the gate oxide film 15 as a common layer with the gate electrodes G1 and G2. The gate oxide film 15 has therein openings 15a for allowing the coupling line 21 to pass therethrough.

For obtaining the structure of the present embodiment, the shallow trench 14 has a specific pattern for defining the extensions 13b of the body areas, the gate oxide film 15 has openings 15a therein for receiving the coupling lines 12, the step of patterning for the gate electrodes G1 and G2 is used to form the coupling lines 21. In the present embodiment, each gate electrode G1 or G2 has a T-shaped end for covering the boundary between the source/drain regions 16P and 16N and the extensions 14b, the T-shaped end preventing a short-circuit failure which may be caused by a later silicide process of the source/drain regions 16P and 16N.

In the present embodiment, the electrical coupling between the body areas PB1 and PB2 of the pMOSFETs PT1 and PT2 as well as the electrical coupling between the body areas NB1 and NB2 of the nMOSFETs NT1 and NT2 allows cancellation of dynamic components of fluctuations of the body potentials V(PB1), V(PB2), V(NB1) and V(NB2) caused by ON/OFF of the MOSFETs, similarly to the first embodiment, to prevent hysteresis of the delay time of the MOSFETs while assuring a high operational speed of the buffer circuit.

It is to be noted that the-present invention is not limited to the semiconductor device having a two-stage buffer circuit such as shown in FIG. 1, and may be applied to any semiconductor device having a plurality of MOSFETs, at least two of which operate in opposite phases. That is, if one of the MOSFETs is tuned ON, another or others of the MOSFETs are turned OFF, and vice versa.

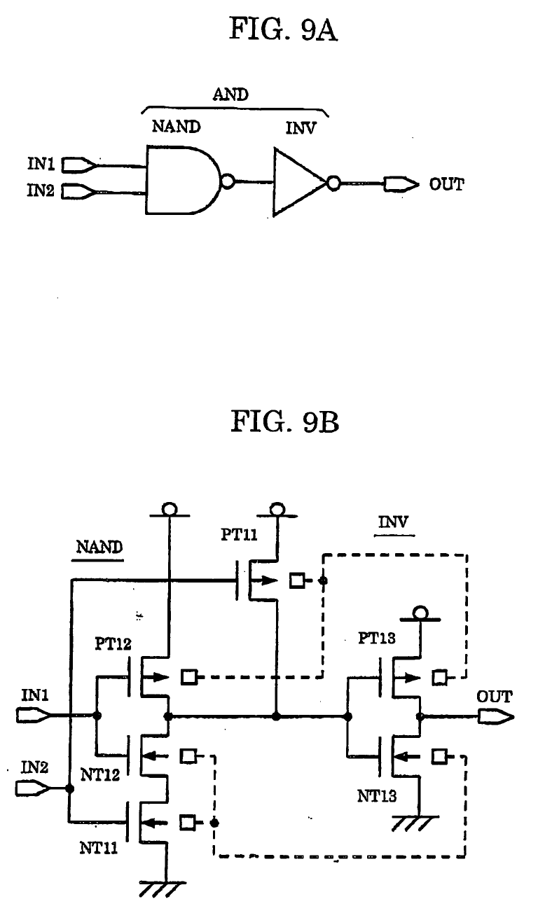

Referring to FIG. 9A, there is shown a first modification modified from FIG. 1, which includes an AND circuit including a NAND gate and an inverter gate cascaded from the NAND gate. FIG. 9B is a circuit diagram of the AND circuit of FIG. 9A. As shown in FIG. 9B, the NAND gate includes first and second pMOSFETs PT11 and PT12 connected in parallel, and first and second nMOSFETs NT11 and NT12 connected in series with each other and with the parallel pMOSFETs PT11 and PT12. The inverter gate includes a third pMOSFET PT13 and a third nMOSFET NT13 connected in series. A first input signal IN1 is applied to the gates of pMOSFET PT12 and nMOSFET NT12, and a second input signal IN2 is applied to gates of pMOSFET PT11 and nMOSFET NT11. The gates of pMOSFET PT13 and nMOSFET NT13 are connected to the node connecting together the drains of parallel pMOSFETs PT11 and PT12 and nMOSFET NT12. The node connecting together the drains of pMOSFET PT13 and nMOSFET NT13 is connected to the output node OUT of the AND circuit.

In the above configuration, pMOSFET PT11 or PT12 and pMOSFET PT13 operate in opposite phases, whereas nMOSFET NT11 or NT12 and nMOSFET NT13 operate in opposite phases. The body areas of pMOSFETs PT11, PT12 and PT13 are coupled together, and the body areas of nMOSFETs NT11, NT12 and NT13 are coupled together, as illustrated by the dotted lines. This allows the dynamic components of the fluctuation of the body potential of pMOSFET PT11 or PT12 (or nMOSFET NT11 or NT12) to be cancelled by the body potential of pMOSFET PT13 (or NT13) operating in opposite phase with pMOSFET PT11 or PT12 (NT11 or NT12), similarly to the first embodiment. The coupling line may be a portion of the semiconductor layer shown in the first embodiment or an overlying interconnect line shown in the second embodiment.

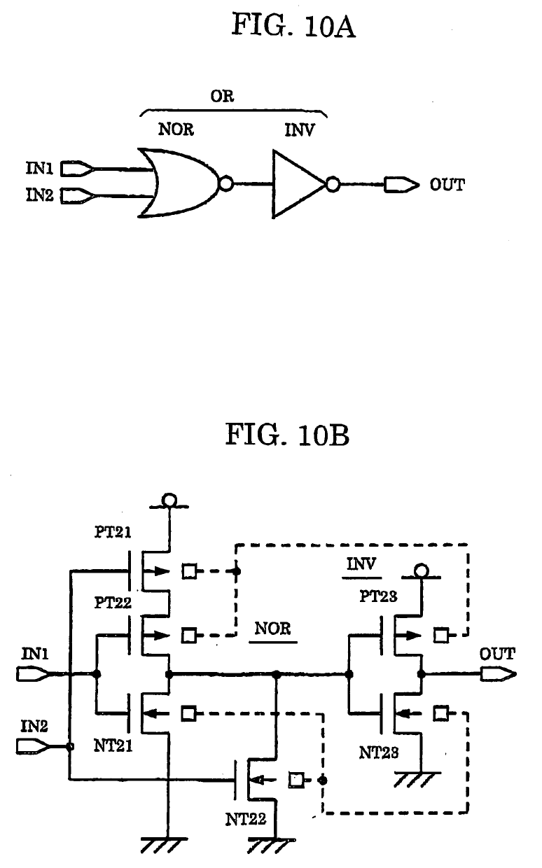

Referring to FIG. 10A, there is shown a second modification modified from FIG. 1, which includes an OR circuit including a NOR gate and an inverter gate cascaded from the NOR gate. FIG. 10B is a circuit diagram of the OR circuit of FIG. 10A. As shown in FIG. 10B, the NOR gate includes first and second pMOSFETs PT21 and PT22 connected in series, and first and second nMOSFETs NT21 and NT22 connected in parallel with each other and in series with the serial first and second pMOSFETs PT21 and PT22. The inverter gate includes a third pMOSFET PT23 and a third nMOSFET NT23 connected in series. A first input signal IN1 is applied to the gates of the second pMOSFET PT22 and first nMOSFET NT21, and a second input signal IN2 is applied to gates of the first pMOSFET PT21 and second nMOSFET NT22. The gates of the third pMOSFET PT13 and third nMOSFET NT13 are connected to the node connecting together the drains of the second pMOSFET PT22 and first nMOSFET NT21. The node connecting together the drains of the third pMOSFET PT23 and third nMOSFET NT23 is connected to the output node OUT of the OR circuit.

In the above configuration, pMOSFET PT21 or PT22 and pMOSFET PT23 operate in opposite phases, whereas nMOSFET NT21 or NT22 and nMOSFET NT23 operate in opposite phases. The body areas of pMOSFETs PT11, PT12 and PT13 are coupled together and the body areas of nMOSFETs NT11, NT12 and NT13 are coupled together, as illustrated by the dotted lines. This configuration allows the dynamic components of the fluctuation of the body potential of pMOSFET PT11 or PT12 (or nMOSFET NT11 or NT12) to be cancelled by the body potential of pMOSFET PT13 (or NT13) operating in opposite phase with pMOSFET PT11 or PT12 (nMOSFET NT11 or NT12), similarly to the first modification. The coupling line may be a portion of the semiconductor layer shown in the first embodiment or an overlying interconnect line shown in the second embodiment.

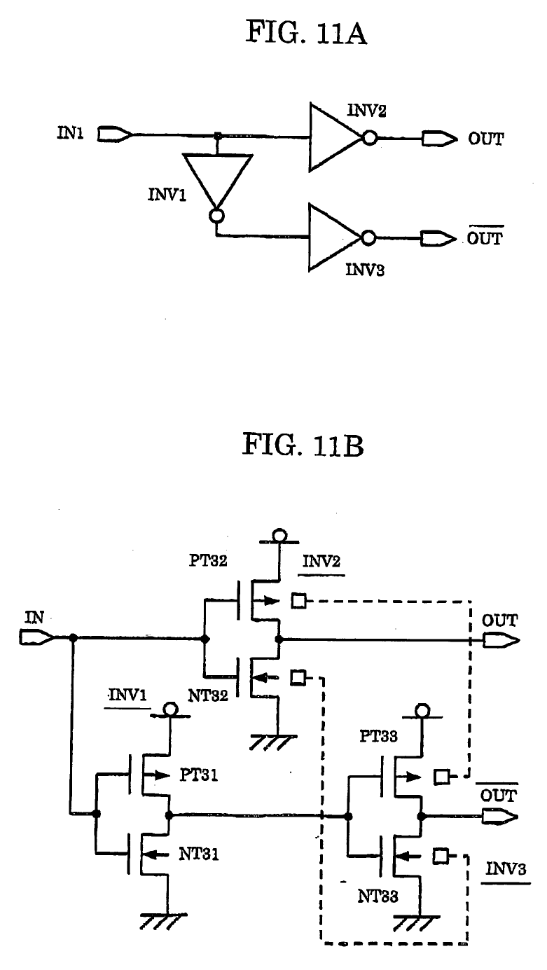

Referring to FIG. 11A, there is shown a third modification from FIG. 1, which includes a logic circuit including three inverter gates INV1, INV2 and INV3. FIG. 11B is a circuit diagram of the logic circuit of FIG. 10A. As shown in FIG. 1A, an input signal IN is applied to inverter gates INV1 and INV2, the latter delivering an output signal OUT. Inverter gate INV3 receives an output from inverter gate INV1 to deliver an output signal /OUT, wherein “/OUT” means an inverted signal of “OUT”. Inverter gates INV2 and INV3 receive a complementary input signal pair to deliver a complementary output signal pair.

As shown in FIG. 11B, inverter gate INV1 includes pMOSFET PT31 and nMOSFET NT31, inverter gate INV2 includes pMOSFET PT32 and nMOSFET NT32, and inverter gate INV3 includes pMOSFET PT33 and nMOSFET NT33. In this configuration, pMOSFETs PT32 and PT33 operate in opposite phases whereas nMOSFETs NT32 and NT33 operate in opposite phases. The body areas of pMOSFETs PT32 and PT33 are coupled together, and the body areas of nMOSFETs NT32 and NT33 are coupled together, as shown by dotted lines. The coupling line may be a portion of the semiconductor layer shown in the first embodiment or an overlying interconnect line shown in the second embodiment.

As described above with reference to the first to third modifications, by coupling the body areas of MOSFETs operating in opposite phases, hysteresis of delay time of the circuits can be suppressed while assuring a higher operational speed of the circuits due to the floating level of the body areas.

The electrical coupling between the body areas of MOSFETs in the present invention is not limited to the configurations as recited above, and may be modified as desired. For example, the coupling line may be such that a portion of insulator in the shallow trench is replaced by a semiconductor material left in the shallow trench. Such a semiconductor material may be doped with impurities for obtaining a lower resistivity. The body areas may be coupled via a metallic line overlying the semiconductor layer.

The principle of the present invention can be applied to a plurality of FETs having the same conductivity-type (or common conductivity-type) and operating in opposite phases.

It is to be noted that the term “maintained at a floating state” does not exclude the configuration wherein the body areas are connected to the ground line by an interconnection or conductive layer having a relatively high impedance so long as the interconnection or conductive layer allows the body potential to temporarily fluctuate during signal transitions of the drain regions etc. in the MOSFETs.

Since the above embodiments are described only for examples, the present invention is not limited to the above embodiments and various modifications or alterations can be easily made therefrom by those skilled in the art without departing from the scope of the present invention.

What is claimed is:

1. A semiconductor integrated circuit (LSI) comprising an insulator layer, a plurality of island semiconductor areas formed on said insulator layer, and a plurality of first field-effect transistors (FETs) having a first conductivity-type and each formed in one of said semiconductor areas, each of said first FETs having a gate electrode, source/drain regions and a body area received in one of said semiconductor areas to oppose said gate electrode, wherein two of said first FETs operating in opposite phases have respective said body areas electrically coupled together via a coupling line and maintained at a floating state.

2. The LSI according to claim 1, wherein said first FETs include a plurality of other FETs other than said two of said first FETs, said body areas of said other FETs are electrically isolated from said two of said first FETs by at least one trench.

3. The LSI according to claim 2, wherein said coupling line is an extension of said body areas passing below a bottom of said trench.

4. The LSI according to claim 1, wherein said coupling line overlies said body areas.

5. The LSI according to claim 4, wherein said coupling line is formed as a common layer with said gate electrode.

6. The LSI according to claim 1, further comprising a plurality of second FETs having a second conductivity-type opposite to said first conductivity-type and each formed in another of said semiconductor areas, each of said second FETs having a gate electrode, source/drain regions and a body area received in said semiconductor areas to oppose said gate electrode, wherein two of said second FETs operating in opposite phases have respective said body areas electrically coupled together via another coupling line and maintained at a floating state.

7. The LSI according to claim 6, wherein one of said two of said first FETs and one of said two of said second FETs form a first inverter, the other of said two of said first FETs and the other of said two of said second FETs form a second inverter cascaded from said first inverter.

8. The LSI according to claim 6, wherein said first FETs include another of said first FETs, said second FETs include another of said second FETs, said body area of said another of said first FETs and said body area of said another of said second FETs are coupled to said body areas of said two of said first FETs and said body areas of said two of said second FETs, respectively.

9. The LSI according to claim 8, wherein one of said two of said first FETs, said another of said first FETS, one of said two of said second FETs and said another of said second FETs form a NAND gate, and the other of said two of said first FETs and the other of said two of said second FETs form an inverter gate cascaded from said NAND gate.

10. The LSI according to claim 8, wherein one of said two of said first FETs, said another of said first FETs, one of said two of said second FETs and said another of said second FETs form a NOR gate, and the other of said two of said first FETs and the other of said two of said second FETs form an inverter gate cascaded from said NOR gate.

11. The LSI according to claim 6, wherein one of said two of said first FETs and one of said two of said second FETs form a first inverter, the other of said two of said first FETs and the other of said two of said second FETs form a second inverter, and said first inverter and said second inverter receive a complementary input signal pair
